(19) United States
(12) Patent Application Publication
(10) Pub. No.: US 2011/0254579 A1
(43) Pub. Date: Oct. 20, 2011

(54) SEMICONDUCTOR TEST METHOD AND SEMICONDUCTOR TEST SYSTEM

(75) Inventor: Satoru Takeda, Ebina-shi (JP)

(73) Assignee: KABUSHIKI KAISHA TOSHIBA, Tokyo (JP)

(21) Appl. No.: 12/951,426

(22) Filed: Nov. 22, 2010

(30) Foreign Application Priority Data
Apr. 15, 2010 (JP) 2010-94192

(51) Int. Cl. G01R 31/26

(52) U.S. Cl. 324/762.01

(57) ABSTRACT

According to an embodiment, a semiconductor test method for performing electrical tests with a plurality of test items on each of the same type of semiconductor devices by semiconductor test equipment is disclosed. The method includes: dividing the plurality of test items into M (M is an integer greater than or equal to 2) test item groups, the M test item groups comprising a test item group that can be performed using a predetermined number of pins of the semiconductor test equipment and M−1 test item groups that can be performed using a certain number of pins of the semiconductor test equipment, the certain number being smaller than the predetermined number; making each pin connection for performing a test of corresponding test item group between the semiconductor test equipment and the M semiconductor devices; and performing tests of each test item group at the same time by the semiconductor test equipment, after making the pin connections.

### CROSS REFERENCE TO RELATED APPLICATIONS

This application is based upon and claims the benefit of priority from the prior Japanese Patent Application No. 2010-94192 filed on Apr. 15, 2010 in Japan, the entire contents of which are incorporated herein by reference.

### FIELD

Embodiments described herein relate generally to a semiconductor test method and a semiconductor test system.

### BACKGROUND

In an electrical test of the same type of semiconductor devices, the number of semiconductor devices to be tested at the same time is adjusted in accordance with the number of pin resources of semiconductor test equipment (tester) and the number of pins used for one semiconductor device, and a plurality of semiconductor devices are measured at the same time. In this way, the testing efficiency is improved.

The semiconductor test equipment has signal pin resources including a plurality of pins for transmitting and receiving signals to and from semiconductor devices. In addition, the semiconductor test equipment also includes a power supply resource for supplying power to the semiconductor devices and an analog resource for performing an analog measurement. The semiconductor test equipment and the semiconductor devices to be tested are connected to each other physically and electrically via a probe card, or a test board and a semiconductor socket.

For example, consider a case in which the semiconductor devices includes signal pin resources of 1024 pins and the number of pins used for one semiconductor device during testing exceeds 512. In this case, the signal pin resources are consumed by the number of pins used for one semiconductor device. Therefore, the number of remaining signal pin resources that are not used does not reach the number of pins used for one semiconductor device, and thus it is impossible to increase the number of semiconductor devices to be tested at the same time. Because of this, many signal pin resources of the semiconductor test equipment are not used and become useless. In the case of this example, a probe card or a test board for measuring one device is used.

Specifically, depending on a relationship between the number of signal pin resources (PR) of the semiconductor test equipment and the number of pins (DP) used for one semiconductor device, there is a case in which the number of pins that are not used (PR−N (semiconductor devices to be tested at the same time)×DP) does not reach DP, in other words, there is a case in which (N+1) semiconductor devices cannot be tested at the same time. In such a case, there is a problem that many signal pin resources are not used and become useless.

### BRIEF DESCRIPTION OF THE DRAWINGS

FIG. 1 is a schematic configuration diagram of semiconductor test equipment and semiconductor devices according to the first embodiment of the present invention.

FIG. 2 is a schematic configuration diagram of a probe card and a test board according to the first embodiment of the present invention.

FIG. 3 is an illustration of an operation of the semiconductor test equipment according to the first embodiment of the present invention.

FIG. 4 is an illustration of a measurement for measuring M×N devices according to the first embodiment of the present invention.

FIG. 5 is a schematic configuration diagram of semiconductor test equipment and semiconductor devices according to the second embodiment of the present invention.

FIG. 6 is a flowchart showing an operation of the semiconductor test equipment according to the second embodiment of the present invention.

FIG. 7 is a schematic configuration diagram of the semiconductor test system according to the third embodiment of the present invention.

FIG. 8 is an illustration of an operation of the semiconductor test system according to the third embodiment of the present invention.

FIG. 9 is a schematic configuration diagram of the semiconductor test system according to the fourth embodiment of the present invention.

FIG. 10 is an illustration of an operation of the semiconductor test system according to the fourth embodiment of the present invention.

### DETAILED DESCRIPTION

According to an embodiment, a semiconductor test method for performing electrical tests with a plurality of test items on each of the same type of semiconductor devices by semiconductor test equipment is disclosed. The method includes: dividing the plurality of test items into M (M is an integer greater than or equal to 2) test item groups, the M test item groups comprising a test item group that can be performed using a predetermined number of pins of the semiconductor test equipment and M−1 test item groups that can be performed using a certain number of pins of the semiconductor test equipment, the certain number being smaller than the predetermined number; making each pin connection for performing a test of corresponding test item group between the semiconductor test equipment and the M semiconductor devices; and performing tests of each test item group at the same time by the semiconductor test equipment, after making the pin connections.

Hereinafter, embodiments according to the present invention will be described with reference to the drawings. These embodiments do not limit the present invention.

### First Embodiment

One of the features of a first embodiment is that a plurality of test items are divided into a test item group that can be performed using a predetermined number of pins of semiconductor test equipment and a test item group that can be performed using the number of pins which is smaller than the predetermined number of pins, and the tests of each test item group are performed on different semiconductor devices at the same time.

More specifically, tests of the semiconductor device include a test which can be performed using a part of terminals of the semiconductor device, such as a scan test and a built-in self test (hereinafter referred to as BIST), by an easily testable design and a test which can be performed using many terminals of the semiconductor device, such as a DC test and a function test. Therefore, tests of semiconductor devices are performed by: using a probe card or a test board to which pins are connected to test the test item group that can be performed using a part of terminals such as the former tests and to which pins are connected to test the test item group that can be performed using many terminals such as the latter tests; and semiconductor test equipment that includes a plurality of control equipment (CPUs) and can perform different tests at the same time.

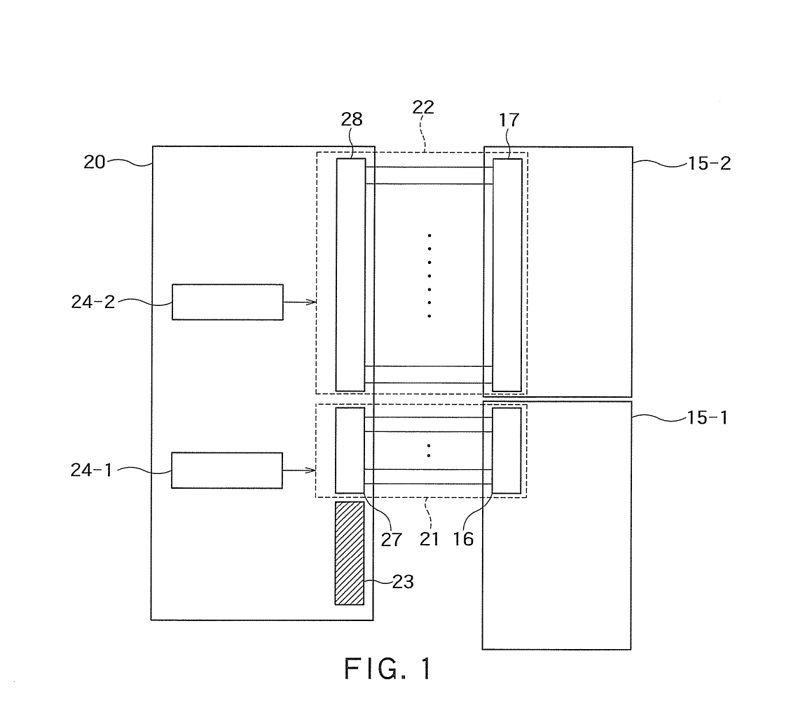

FIG. 1 is a schematic configuration diagram of semiconductor test equipment and semiconductor devices according to the first embodiment of the present invention.

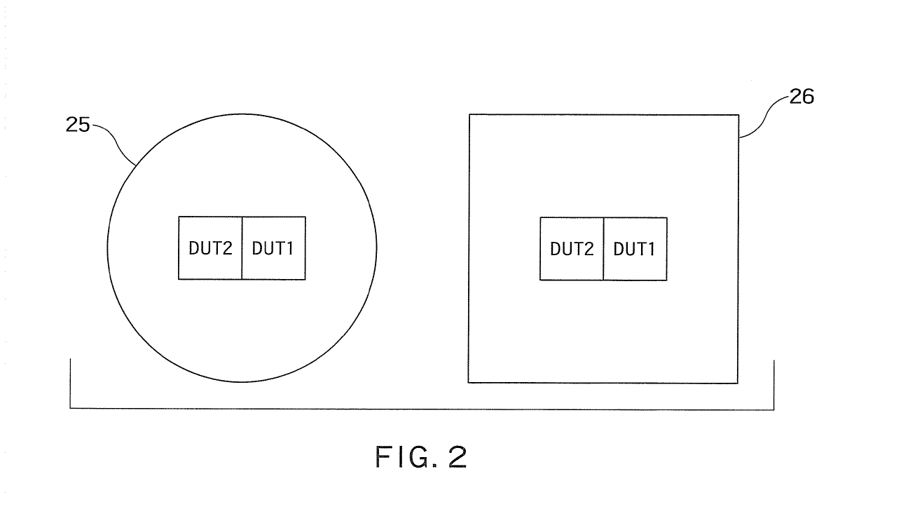

FIG. 2 is a schematic configuration diagram of a probe card and a test board according to the first embodiment of the present invention.

Each of the same type of semiconductor devices 15-1 and 15-2 is tested for a plurality of test items. The plurality of test items are divided into two test item groups TG1 and TG2. The test item group TG1 includes tests that can be performed using a part of terminals, such as the scan test and the BIST. The test item group TG2 includes tests that are not included in the test item group TG1 and use many terminals. After dividing the test items, pin connection 21 for testing the test item group TG1 is performed between pins 27 of semiconductor test equipment 20 and terminals 16 of the semiconductor device 15-1. Also, pin connection 22 for testing the test item group TG2 is performed between pins 28 of the semiconductor test equipment 20 and terminals 17 of the semiconductor device 15-2.

These pin connections 21 and 22 are performed by connecting the semiconductor test equipment 20 with the semiconductor devices 15-1 and 15-2 via the probe card 25 or the test board 26 shown in FIG. 2. The former pin connection 21 for testing the test item group TG1 that can be performed using a part of terminals corresponds to a connection of the probe card 25 or the test board 26 to DUT1. The latter pin connection 22 for testing the test item group TG2 corresponds to a connection to DUT2. In descriptions of the present embodiments herein, when a probe card is used, the DUT represents an area where the probe to the semiconductor device to be tested is placed, and when a test board is used, the DUT represents a socket in which the semiconductor device to be tested is mounted.

The semiconductor test equipment 20 includes a plurality of control devices 24-1 and 24-2, and can perform different tests at the same time using the pin connections 21 and 22 on the basis of controls of the control devices 24-1 and 24-2. The semiconductor test equipment 20 is assumed to be one of semiconductor test equipment released by semiconductor test equipment manufacturers.

Pins 23 of the semiconductor test equipment 20 are not used.

Next, an operation of the semiconductor test equipment according to the first embodiment of the present invention will be described in comparison with a comparative example. Here, a case in which a semiconductor device formed on a wafer is tested will be described.

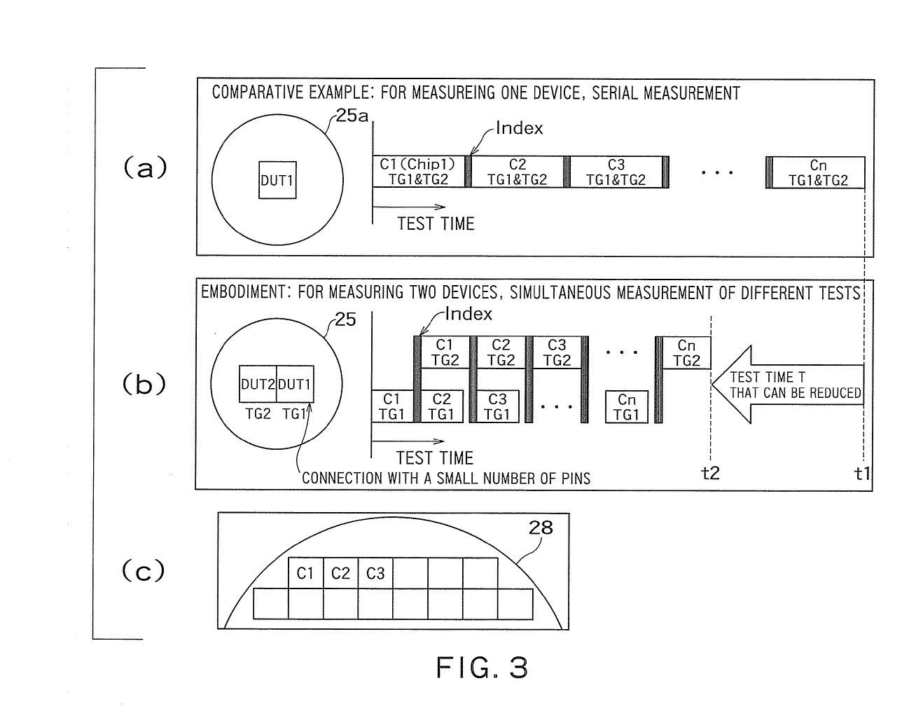

FIG. 3 is an illustration of an operation of the semiconductor test equipment according to the first embodiment of the present invention.

FIG. 3(a) shows a configuration of a probe card for measuring one device and a testing operation using this probe card as a comparative example. FIG. 3(b) shows a configuration of a probe card for measuring two devices and a testing operation using this probe card as the present embodiment. FIG. 3(c) shows a plan view of a part of a wafer on which the semiconductor device to be tested is formed.

In descriptions of the present embodiments herein, “measuring X devices” means that X semiconductor devices can be measured (tested) at the same time.

In the comparative example in FIG. 3(a), tests of a plurality of test item groups TG1 and TG2 are serially measured. Specifically, first, a probe (not shown in FIG. 3) of the DUT1 of the probe card 25a comes into contact with a chip (semiconductor device) C1 on a wafer 28 physically and electrically, and in this state, tests of the test item group TG1 and the test item group TG2 are sequentially performed. Next, by an index operation, the probe comes into contact with a chip C2, and the tests are performed in the same manner. Thereafter, tests are performed in the same manner until chip Cn is tested, and tests of the chips for one row on the wafer 28 are completed at time t1. The index operation represents a series of operations in which the wafer moves and the probe in contact with a chip on the wafer detaches from the chip and comes into contact with a chip to be tested next.

In the present embodiment shown in FIG. 3(b), as shown in FIG. 2, the probe card 25 is used which is for measuring 2 devices. With the probe card 25, the test item group TG1 that can be performed using a part of terminals is performed by the DUT1, and the test item group TG2 including tests that are not included in the test item group TG1 is performed by the DUT2.

First, a probe (not shown in FIG. 3) of the DUT1 of the probe card 25 comes into contact with the chip C1 physically and electrically, and tests of the test item group TG1 are performed. Next, when the tests of the test item group TG1 are completed, by the index operation, the probe of the DUT1 comes into contact with the chip C2 and a probe of the DUT2 comes into contact with the chip C1. Then, the tests of the test item group TG1 are performed on the chip C2, and at the same time, the tests of the test item group TG2 are performed on the chip C1. Next, when the tests of the test item group TG2 are completed, the index operation is performed, and thereafter, the tests are performed in the same manner. At the end of each row on the wafer 28, only the probe of the DUT2 comes into contact with a chip physically and electrically, and the tests of the test item group TG2 are performed. In this way, the tests of the chips for one row on the wafer 28 are completed at time t2. It is assumed that the test time of the test item group TG1 is shorter than the test time of the test item group TG2.

As described above, since the positional relationship between the chips on the wafer 28 is fixed during the wafer measurement, there is a restriction in the physical contact between the probe of the probe card 25 and the semiconductor device. Therefore, the tests of the test item group TG1 performed for the first time in each row on the wafer 28 and the tests of the test item group TG2 performed for the last time in each row on the wafer 28 are performed on one chip respectively.

However, other than the above, it is possible to perform different tests of the test item group TG1 and the test item group TG2 on different chips at the same time, thus the test time can be reduced compared with the comparative example. In the test for one row on the wafer 28 shown in FIG. 3, the test time T that can be reduced from the test time of the comparative example can be represented as [(n−1)×test time of the test item group TG1] when the number of chips in one row on the wafer 28 is represented by n.

For a test for one wafer, the test time that can be reduced from the test time of the comparative example can be represented as follows:

(1) In a case of “the test time of the test item group TG1<the test time of the test item group TG2”,

the test time that can be reduced=the total sum of each row's [(the number of chips in one row−1)×test time of the test item group TG1]

(2) In a case of “the test time of the test item group TG1>the test time of the test item group TG2”,

the test time that can be reduced=the total sum of each row's [(the number of chips in one row−1)×test time of the test item group TG2]

As described above, according to the present embodiment, a plurality of test items are divided into a test item group that can be performed using a predetermined number of pins of the semiconductor test equipment and a test item group that can be performed using the number of pins which is smaller than the predetermined number of pins, and the tests of each test item group are performed on different semiconductor devices at the same time. Accordingly, it is possible to reduce unused pin resources of the semiconductor test equipment, perform different tests at the same time, and reduce the test time.

In other words, in a case in which many pins remain unused due to a relationship between the number of pin resources of the semiconductor test equipment and the number of pins used for one semiconductor device, the unused pin resources can be effectively used.

Based on this arrangement, when the semiconductor devices are mass-produced, it is possible to reduce the test time and reduce the manufacturing cost of the semiconductor devices.

Although, in the present embodiment, an example of the case in which the test items are divided into two test item groups is described, if the number of pin resources of the semiconductor devices is large enough to further increase the test item groups, it is possible to divide the test items into more than two test item groups. In addition, considering analog resources, an analog test item group may be divided from the other test item groups. In other words, the test item group that can be performed using the number of pins which is smaller than the predetermined number of pins may include a test item of a test for each function block such as a high-speed interface block and an analog block.

Specifically, a plurality of test items are divided into M (M is an integer greater than or equal to 2) test item groups including a test item group that can be performed using a predetermined number of pins of the semiconductor test equipment and M−1 test item groups that can be performed using the certain number of pins of the semiconductor test equipment, the certain number being smaller than the predetermined number. And each pin connection for testing the test item groups is made between the semiconductor test equipment and M semiconductor devices, and thereafter, the tests of each test item group may be performed at the same time by the semiconductor test equipment.

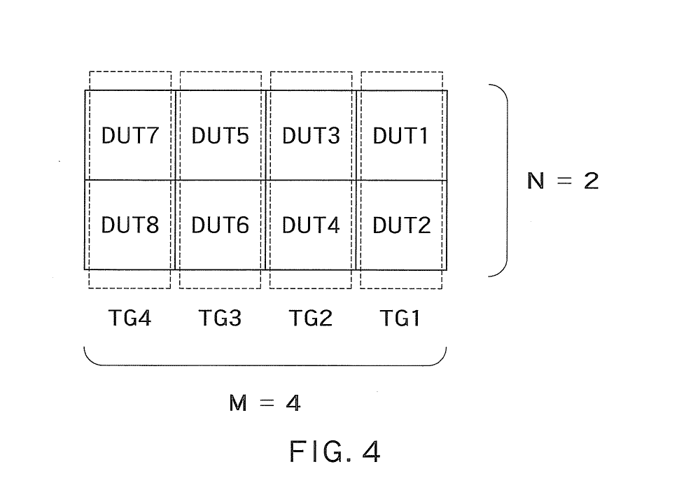

Further, while the comparative example shows an example of measuring one device and the present embodiment shows an example of measuring two devices at the same time, as shown in FIG. 4, a measurement for measuring N devices may be changed to a measurement for measuring M×N devices by dividing the test items into M test item groups. In other words, the N semiconductor devices can be tested for each test item group.

While an example of the wafer measurement is described in the present embodiment, a package measurement can be performed using the test board 26.

Although it is described that there is a restriction in the physical contact between the probe card and the semiconductor device in the example of the wafer measurement of FIG. 3, there is no such restriction in the package measurement. Therefore, by arranging the test sequence, such as, for example, separating the semiconductor devices tested from the test item group TG1, from the semiconductor devices tested from the test item group TG2 in advance, it is possible to prevent reduction loss of the test time. The details of the above will be described later in a fourth embodiment.

### Second Embodiment

One of the features of a second embodiment is that a test result holding section for holding test results of the tested semiconductor devices is added to the semiconductor test equipment described in the first embodiment.

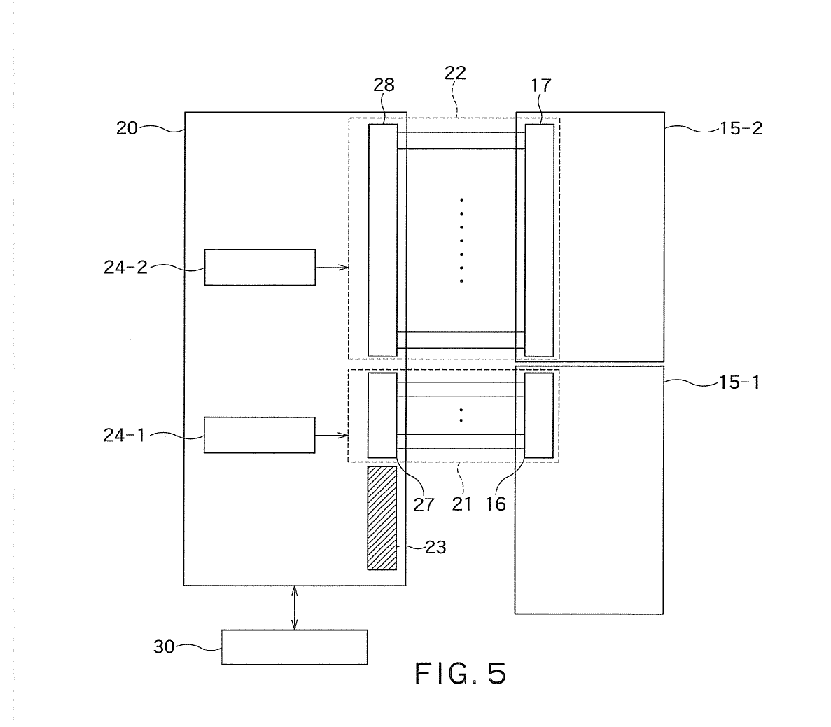

FIG. 5 is a schematic configuration diagram of semiconductor test equipment and semiconductor devices according to the second embodiment of the present invention. The same reference numerals are given to the same elements as those shown in the first embodiment in FIG. 1, their description will not be repeated, and only different portions will be described.

A test result holding section 30 defines, for example, common variables in a test program, and holds coordinates and numbers identifying the tested semiconductor devices, the number of performed test item groups (serial number), and test results of each test item group by using the common variables. On the basis of the above information, for each semiconductor device, when a test result of a certain test item group is determined to be good, the semiconductor test equipment 20 performs test of the next test item group. When the test result is determined to be not good, the semiconductor test equipment 20 does not perform tests of the next and following test item groups, and determines the final test result based on the test result of the last test item group.

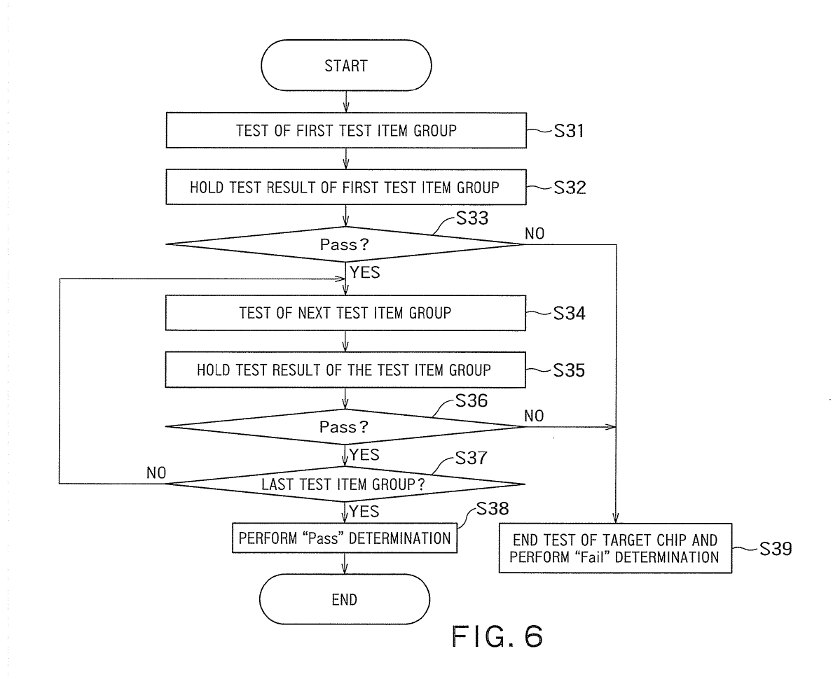

Further details of the above will be described with reference to FIG. 6. FIG. 6 is a flowchart showing an operation of the semiconductor test equipment according to the second embodiment of the present invention.

First, test of a first test item group is performed on a target chip by the semiconductor test equipment 20 (step S31). Next, the test result of the first test item group is held by the test result holding section 30 (step S32). Next, whether or not the test result is “pass” (good) is determined by the semiconductor test equipment 20 (step S33). If the test result is “fail” (not good), the test of the target chip ends and the test result is determined to be “fail” (step S39).

If the test result is “pass” in step S33, test of the next test item group is performed by the semiconductor test equipment 20 (step S34). Next, the test result of the test item group is held by the test result holding section 30 (step S35).

Next, whether or not the test result is “pass” is determined by the semiconductor test equipment 20 (step S36). If the test result is “fail”, the test of the target chip ends and the test result is determined to be “fail” (step S39).

If the test result is “pass” in step S36, whether or not the test item group is the last test item group is determined by the semiconductor test equipment 20 (step S37). If the test item group is not the last test item group, the process is repeated from step S34. If the test item group is the last test item group, the target chip is determined to be “pass” (step S38).

In a case of the package measurement, for example, a semiconductor device determined to be “fail” may be removed before reaching the test of the last test item group.

In this way, according to the present embodiment, for each semiconductor device, the semiconductor test equipment 20 holds test results of the test item groups, and when a test result of a certain test item group is determined to be good, the semiconductor test equipment 20 performs test of the next test item group. When the test result is determined to be not good, the semiconductor test equipment 20 does not perform tests of the next and following test item groups, and determines the final test result based on the test result of the last test item group. Thus, it is possible to efficiently determine whether the semiconductor device is good or not.

In addition, the same effect as that of the first embodiment can be obtained.

### Third Embodiment

A third embodiment relates to a semiconductor test system in which probing equipment (prober) is added to the configuration of the first embodiment and wafer measurement is performed.

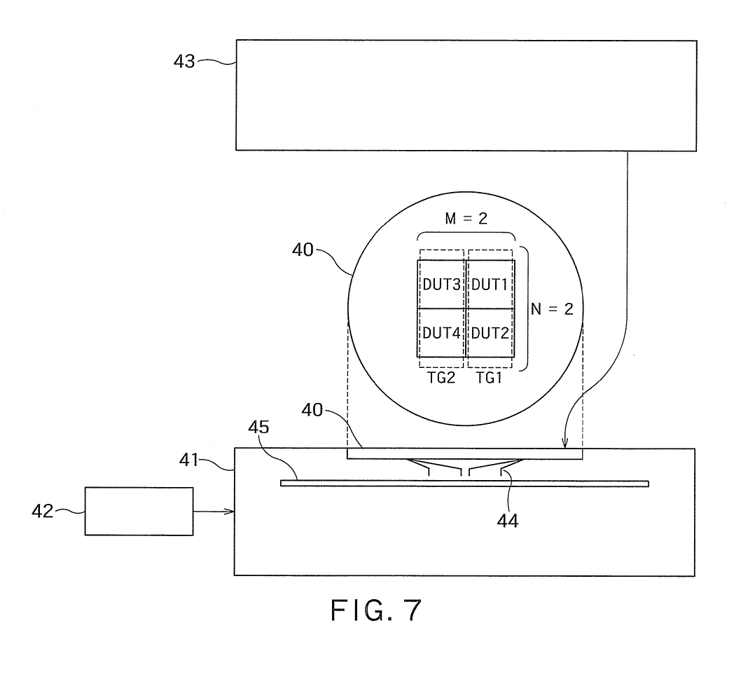

FIG. 7 is a schematic configuration diagram of the semiconductor test system according to the third embodiment of the present invention.

As shown in FIG. 7, the semiconductor test system includes a probe card 40 for measuring M×N devices (M is an integer greater than or equal to 2, N is a positive integer), probing equipment 41, control equipment 42 for causing the probing equipment 41 to perform an index operation of a unit of N which is the number of semiconductor devices on which the test of one test item group is performed at the same time, and semiconductor test equipment 43 which includes a plurality of control equipment (not shown in FIG. 7) and can perform different electrical tests at the same time. For ease of explanation, FIG. 7 also shows a top view of the probe card 40.

The semiconductor test system performs electrical tests with a plurality of test items on each of the same type of semiconductor devices formed on a semiconductor wafer 45 by using semiconductor test equipment 43 similar to the semiconductor test equipment of the first embodiment. In the same manner as in the first embodiment, the plurality of test items are divided into M test item groups including a test item group that can be performed using a predetermined number of pins of the semiconductor test equipment 43 and M−1 test item groups that can be performed using a certain number of pins of the semiconductor test equipment, the certain number being smaller than the predetermined number.

The probe card 40 includes a plurality of probes 44 that can electrically come into contact with M×N semiconductor devices, and pin connections for testing N semiconductor devices for each test item group have been made between the semiconductor test equipment 43 and the plurality of probes 44.

Based on this, the semiconductor test equipment 43 can electrically come into contact with each semiconductor device formed on the wafer 45 via the probes 44.

The probing equipment 41 moves the wafer 45 to perform the index operation.

In the present embodiment, an example will be described in which a plurality of test items are divided into two (M=2) test item groups, and the probe card 40 for measuring 2×2 devices which tests two (N=2) semiconductor devices for each test item group is used.

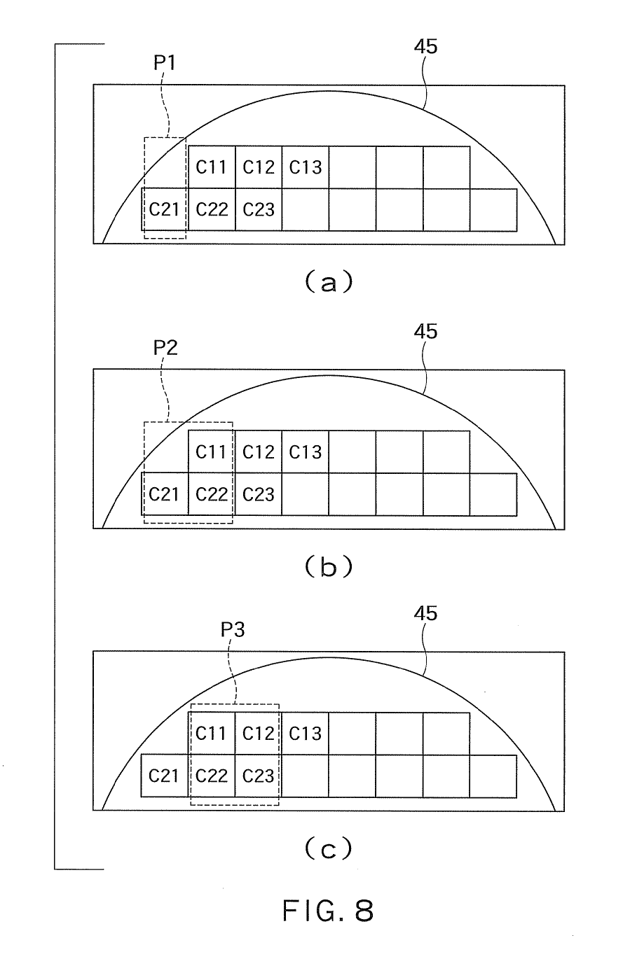

FIG. 8 is an illustration of the index operation of the semiconductor test system according to the third embodiment of the present invention.

In the present embodiment, two semiconductor devices are measured at the same time for one test item group, and therefore, as shown in FIG. 8, the index operation for a unit of vertically aligned two semiconductor devices is performed.

Specifically, first, as shown in FIG. 8(a), the wafer 45 is indexed to the position P1 to cause the probe of the DUT2 to come into contact with chip C21, and the test of the test item group TG1 is performed on the chip C21. Next, as shown in FIG. 8(b), the wafer 45 is indexed to the position P2, so that the probe of the DUT1 is caused to come into contact with chip C11 and the probe of the DUT2 is caused to come into contact with chip C22, and thus the test of the test item group TG1 is performed on the chips C11 and C22. At the same time, the probe of the DUT4 is caused to come into contact with the chip C21, and the test of the test item group TG2 is performed on the chip C21. Next, as shown in FIG. 8(c), the wafer 45 is indexed to the position P3, and the test of the test item group TG1 is performed on the chips C12 and C23. At the same time, the test of the test item group TG2 is performed on the chips C11 and C22. Thereafter, the index operations are performed in the same manner.

As described above, according to the present embodiment, it is possible to perform a wafer probing measurement by the index operation for a unit of the number of semiconductor devices on which the test of one test item group is performed. Therefore, it is possible to reduce unused pin resources of the semiconductor test equipment, perform different tests at the same time, and reduce the test time.

### Fourth Embodiment

A fourth embodiment relates to a semiconductor test system in which handling equipment (handler) is added to the configuration of the first embodiment and package measurement is performed.

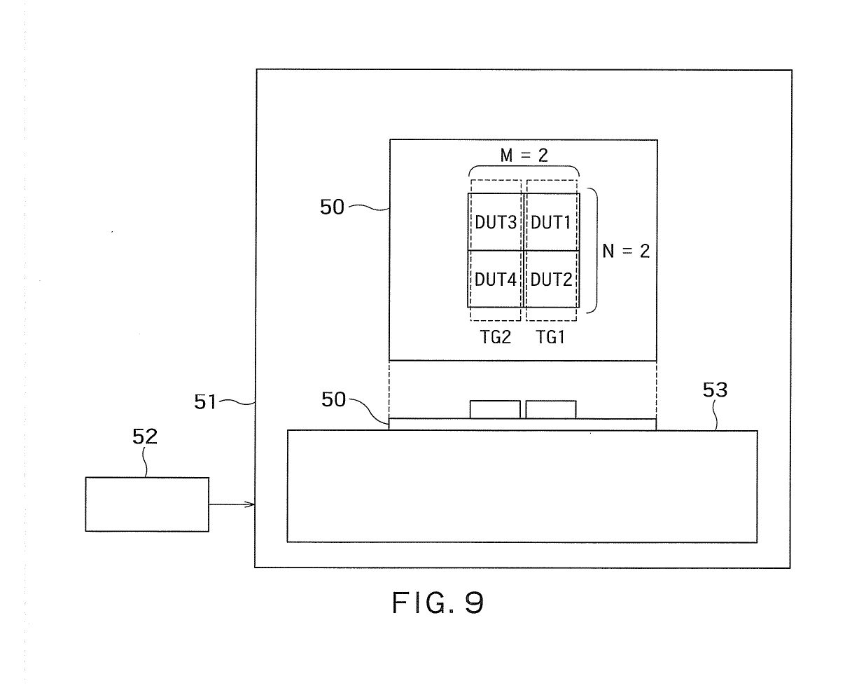

FIG. 9 is a schematic configuration diagram of the semiconductor test system according to the fourth embodiment of the present invention.

As shown in FIG. 9, the semiconductor test system includes a test board 50 for measuring M×N devices (M is an integer greater than or equal to 2, N is a positive integer), handling equipment 51, control equipment 52 for causing the handling equipment 51 to perform handling of semiconductor devices of a unit of N which is the number of semiconductor devices on which the test of one test item group is performed at the same time, and semiconductor test equipment 53 which includes a plurality of control equipment (not shown in FIG. 9) and can perform different electrical tests at the same time. For ease of explanation, FIG. 9 also shows a top view of the test board 50.

The semiconductor test system performs electrical tests with a plurality of test items on each of the same type of packaged semiconductor devices by using semiconductor test equipment 53 similar to the semiconductor test equipment of the first embodiment. In the same manner as in the first embodiment, the plurality of test items are divided into M test item groups including a test item group that can be performed using a predetermined number of pins of the semiconductor test equipment 53 and M−1 test item groups that can be performed using a certain number of pins of the semiconductor test equipment, the certain number being smaller than the predetermined number.

The test board 50 includes DUTs (sockets) and a plurality of terminals (not shown in FIG. 9) that can electrically come into contact with M×N semiconductor devices mounted on DUTs, and pin connections for testing N semiconductor devices for each test item group have been made between the semiconductor test equipment 53 and the plurality of terminals.

Based on this arrangement, the semiconductor test equipment 53 can electrically come into contact with each semiconductor device via the plurality of terminals of the test board 50.

The handling equipment 51 performs handling for moving the semiconductor devices to be tested.

In the present embodiment, an example will be described in which a plurality of test items are divided into two (M=2) test item groups, and the test board 50 for measuring 2×2 devices which tests two (N=2) semiconductor devices for each test item group is used.

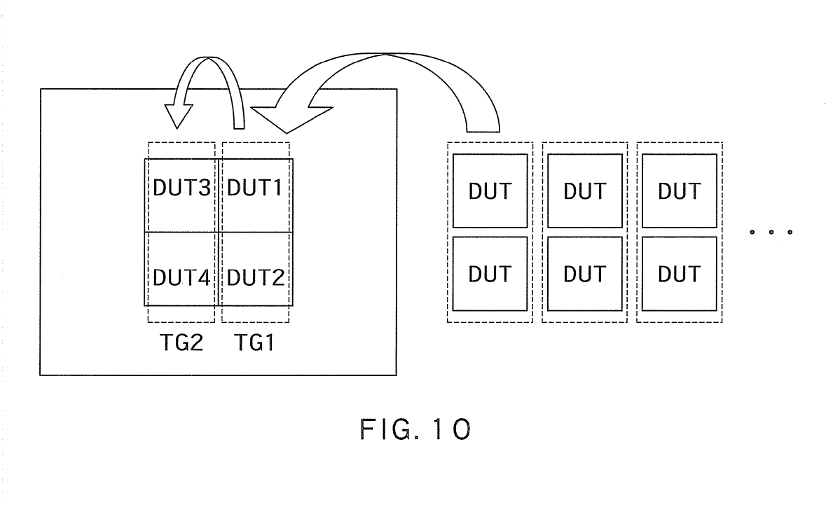

FIG. 10 is an illustration of the handling operation of the semiconductor test system according to the fourth embodiment of the present invention.

In the present embodiment, two semiconductor devices are measured at the same time for one test item group. Therefore, as shown in FIG. 10, the handling equipment 51 handles two semiconductor devices at a time. First, the handling equipment 51 mounts the semiconductor devices on DUT1 and DUT2 of the test board and performs the test of the test item group TG1. At this time, no semiconductor device is mounted on DUT3 and DUT4 of the test board. Next, the handling equipment 51 handles and moves these semiconductor devices to the DUT3 and DUT4 of the test board respectively. At this time, the handling equipment 51 mounts new semiconductor devices on the DUT1 and DUT2 of the test board respectively. Accordingly, the test of the test item group TG2 is performed on the semiconductor devices mounted on the DUT3 and DUT4 of the test board, and at the same time, the test of the test item group TG1 is performed on the semiconductor devices mounted on the DUT1 and DUT2 of the test board. Thereafter, tests are performed in the same manner.

As described in the first embodiment, by arranging the test sequence of a plurality of semiconductor devices, it is possible to prevent reduction loss of the test time and further reduce the test time.

Specifically, the semiconductor devices (group 1) which will be tested from the test item group TG1 and the semiconductor devices (group 2) which will be tested from the test item group TG2 are separated from each other in advance. Then, the test of the test item group TG1 is performed on two semiconductor devices of group 1 at a time by using the DUT1 and DUT2 of the test board. In parallel with the above operation, the test of the test item group TG2 is performed on two semiconductor devices of group 2 at a time by using the DUT3 and DUT4 of the test board.

After the test of the test item group TG1 has been performed on all the semiconductor devices of group 1, the test of the test item group TG1 is performed on semiconductor devices of group 2 on which the test of the test item group TG2 has been performed.

On the other hand, after the test of the test item group TG2 has been performed on all the semiconductor devices of group 2, the test of the test item group TG2 is performed on semiconductor devices of group 1 on which the test of the test item group TG1 has been performed.

With the above arrangement, the test can be performed using the DUT1 to DUT4 of the test board from the beginning, and it is possible to more effectively reduce the test time.

As described above, according to the present embodiment, it is possible to perform a package measurement by the handling of a unit of the number of semiconductor devices on which the test of one test item group is performed, and therefore, it is possible to reduce unused pin resources of the semiconductor test equipment, perform different tests at the same time, and reduce the test time.

According to the embodiments described above, the pin resources of the semiconductor test equipment can be efficiently used.

While certain embodiments have been described, these embodiments have been presented by way of example only, and are not intended to limit the scope of the inventions. Indeed, the novel methods and systems described herein may be embodied in a variety of other forms; furthermore, various omissions, substitutions and changes in the form of the methods and systems described herein may be made without departing from the spirit of the inventions. The accompanying claims and their equivalents are intended to cover such forms or modifications as would fall within the scope and spirit of the inventions.

1. A semiconductor test method for performing electrical tests with a plurality of test items on each of the same type of semiconductor devices by semiconductor test equipment, the semiconductor test method comprising:
dividing the plurality of test items into M (M is an integer greater than or equal to 2) test item groups, the M test item groups comprising a test item group that can be performed using a predetermined number of pins of the semiconductor test equipment and M−1 test item groups that can be performed using a certain number of pins of the semiconductor test equipment, the certain number being smaller than the predetermined number;
making each pin connection for performing a test of corresponding test item group between the semiconductor test equipment and the M semiconductor devices; and
performing tests of each test item group at the same time by the semiconductor test equipment, after making the pin connections.

2. The semiconductor test method of claim 1, further comprising, for each semiconductor device:
holding test results of the test item groups;
if a test result of a certain test item group is good, performing a test of the next test item group; and,
if the test result is not good, not performing tests of the next and following test item groups and determining a final test result based on a test result of a last test item group.

3. The semiconductor test method of claim 1, further comprising:
repeatedly making the pin connection and the test of each test item group, so that tests of the M test item groups are performed on each semiconductor device.

4. The semiconductor test method of claim 1, further comprising:
repeatedly making the pin connection and the test of each test item group, so that tests of the M test item groups are performed on each semiconductor device in the same sequence.

5. The semiconductor test method of claim 1, further comprising:
dividing the semiconductor devices into M groups in advance; and
repeatedly making the pin connection and the test of each test item group so that a test of test item group different for each group is performed on semiconductor devices of each group, and after a test of a certain test item group has been performed on all semiconductor devices of a certain group, the test of the certain test item group is performed on semiconductor devices of another group.

6. The semiconductor test method of claim 1, further comprising:
making the pin connection so that a plurality of the semiconductor devices can be tested for each test item group.

7. The semiconductor test method of claim 1, wherein the semiconductor devices are formed on a semiconductor wafer.

8. The semiconductor test method of claim 7, wherein the pin connection is made by using a probe card.

9. The semiconductor test method of claim 1, wherein the semiconductor devices are packaged semiconductor devices.

10. The semiconductor test method of claim 9, wherein the pin connection is made by using a test board.

11. The semiconductor test method of claim 1, wherein the test item group that can be performed using the predetermined number of pins comprises at least either of a test item of a DC test and a test item of a function test.

12. The semiconductor test method of claim 1, wherein the M−1 test item groups that can be performed using the certain number of pins, the certain number being smaller than the predetermined number, comprise at least any one of a test item of a scan test, a test item of a built-in self test, and a test item of a test for each function block.

13. A semiconductor test system configured to perform electrical tests with a plurality of test items on each of the same type of semiconductor devices formed on a semiconductor wafer by using semiconductor test equipment, the plurality of test items being divided into M (M is an integer greater than or equal to 2) test item groups, the M test item groups comprising a test item group that can be performed using a predetermined number of pins of the semiconductor test equipment and M−1 test item groups that can be performed using a certain number of pins of the semiconductor test equipment, the certain number being smaller than the predetermined number, the semiconductor test system comprising:
a probe card configured to measure M×N devices (N is a positive integer), the probe card comprising a plurality of probes that can electrically come into contact with M×N semiconductor devices, pin connections for testing N semiconductor devices for each test item group being performed between the semiconductor test equipment and the plurality of probes; and
probing equipment configured to perform an index operation of a unit of N, N being the number of the semiconductor devices on which one test item group is performed at the same time;
wherein
the semiconductor test equipment performs tests of the test item groups at the same time.

14. The semiconductor test system of claim 13, further comprising:
a test result holding section configured to hold test results of the test item groups for each semiconductor device;
wherein
for each semiconductor device, when a test result of a certain test item group is good, the semiconductor test equipment performs test of the next test item group, and when the test result is not good, the semiconductor test equipment does not perform tests of the next and following test item groups, and determines a final test result based on a test result of a last test item group.

15. The semiconductor test system of claim 13, wherein the test item group that can be performed using a predetermined number of pins comprises at least either of a test item of a DC test and a test item of a function test.

16. The semiconductor test system of claim 13, wherein the M−1 test item groups that can be performed using a certain number of pins, the certain number being smaller than the predetermined number, comprise at least any one of a test item of a scan test, a test item of a built-in self test, and a test item of a test for each function block.

17. A semiconductor test system configured to perform electrical tests with a plurality of test items on each of the same type of semiconductor devices by using semiconductor test equipment, the plurality of test items being divided into M (M is an integer greater than or equal to 2) test item groups, the M test item groups comprising a test item group that can be performed using a predetermined number of pins of the semiconductor test equipment and M−1 test item groups that can be performed using a certain number of pins of the semiconductor test equipment, the certain number being smaller than the predetermined number, the semiconductor test system comprising:
a test board configured to measure M×N devices (N is a positive integer), the test board comprising a plurality of terminals that can electrically come into contact with M×N semiconductor devices, pin connections for testing N semiconductor devices for each test item group being made between the semiconductor test equipment and the plurality of terminals; and
handling equipment configured to perform handling of the semiconductor devices for a unit of N, N being the number of the semiconductor devices on which one test item group is performed at the same time;
wherein
the semiconductor test equipment performs tests of the test item groups at the same time.

18. The semiconductor test system of claim 17, further comprising:
a test result holding section configured to hold test results of the test item groups for each semiconductor device;
wherein
for each semiconductor device, when a test result of a certain test item group is good, the semiconductor test equipment performs test of the next test item group, and when the test result is not good, the semiconductor test equipment does not perform tests of the next and following test item groups, and determines a final test result based on a test result of a last test item group.

19. The semiconductor test system of claim 17, wherein the semiconductor devices are packaged semiconductor devices.

20. The semiconductor test system of claim 17, wherein
the test item group that can be performed using a predetermined number of pins comprises at least either of a test item of a DC test item and a test item of a function test item, and
the M−1 test item groups that can be performed using a certain number of pins, the certain number being smaller than the predetermined number, comprise at least any one of a test item of a scan test, a test item of a built-in self test, and a test item of a test for each function block.
